(19) United States
(12) Patent Application Publication
(10) Pub. No.: US 2020/0308465 A1
(43) Pub. Date: Oct. 1, 2020

(54) POLYMER COMPOSITIONS EXHIBITING REFLECTIVITY AND THERMAL CONDUCTIVITY

(71) Applicant: SABIC Global Technologies B.V., Bergen op Zoom (NL)

(72) Inventors: Yaqin Zhang, Shanghai (CN); Haowei Tang, Shanghai (CN)

(21) Appl. No.: 16/308,589

(22) PCT Filed: Jun. 9, 2017
(86) PCT No.: PCT/IB2017/053438

§ 371 Date: Dec. 10, 2018

Related U.S. Application Data
(60) Provisional application No. 62/352,587, filed on Jun. 21, 2016.

(51) Int. Cl. C09K 5/14; C08G 69/14; C08L 77/02; C08K 3/34; C08K 3/22; C08K 5/3417; C08K 5/45; C08K 3/38; C08K 13/02; H01L 33/64; H05K 7/20

(52) U.S. Cl. CPC C09K 5/14; C08K 2003/2224; C08L 77/02; C08K 3/34; C08K 3/22; C08K 5/3417; C08K 5/45; C08K 3/38; C08K 13/02; H01L 33/641; H05K 7/2039; C08K 2201/014; C08K 2003/385; C08K 2003/343; C08K 2003/2241; C08G 69/14

(57) ABSTRACT

Polymer resin compositions include a thermally conductive filler and one or more of a white pigment or an optical brightening agent. In a particular aspect a polymer composition includes: from about 20 wt. % to about 80 wt. % of a polymer base resin; from about 1 wt. % to about 70 wt. % of a thermally conductive filler; from about 0.1 wt. % to about 50 wt. % of a white pigment; and from about 0.001 wt. % to about 10 wt. % of an optical brightening agent. In certain aspects the polymer composition exhibits a through plane thermal conductivity of at least about 0.3 W/mK and a reflectivity of at least about 80%. In further aspects the polymer composition exhibits a through plane thermal conductivity of at least about 0.3 W/mK and a reflectivity of at least about 90%.

### TECHNICAL FIELD

The disclosure relates to polymer compositions having an optical brightening agent or a white pigment, or a combination thereof, and a thermally conductive filler.

### BACKGROUND

Fillers can be used to impart certain physical properties to a given polymer composition. Depending upon the profile of the base polymer matrix, these fillers can improve flexural strength, thermal conductivity impact strength, and stability among a wealth of other properties. Filled polymer compositions are increasingly desirable for their versatility and widely applicable field of use.

### SUMMARY

Modifying the properties of a polymer composition through the introduction of varying types of additives is a continuing trend. Properties of thermal conductivity or reflectivity may be imparted to a polymer resin by the introduction of thermally conductive fillers or by white pigments and optical brighteners, respectively. Polymer compositions according to aspects of the present disclosure provide both thermal conductivity and reflectivity. Aspects of the present disclosure relate to a polymer composition including from about 20 wt. % to about 80 wt. % of a polymer base resin; from about 1 wt. % to about 70 wt. % of a thermally conductive filler; from about 0.1 wt. % to about 50 wt. % of a white pigment; and from about 0.001 wt. % to about 10 wt. % of an optically brightening agent. The polymer composition exhibits a through plane thermal conductivity of at least about 0.3 W/mK and a reflectivity of at about least 80%. The polycarbonate composition can further include additional additives and processing aids.

Other aspects of the present disclosure relate to compositions including from about 20 wt. % to about 60 wt. % of a polymer base resin; from about 1 wt. % to about 70 wt. % of a thermally conductive filler; from about 0.1 wt. % to about 25 wt. % of a white pigment; and from about 0.001 wt. % to about 10 wt. % of an optically brightening agent. The polymer composition exhibits a through plane thermal conductivity of at least about 0.3 W/mK and a reflectivity of at least about 80%. The polycarbonate composition can further include additional additives and processing aids.

In yet other aspects, the present disclosure relates to a method of forming a composition including a polymer base resin, one or more of a thermally conductive filler, one or more of a white pigment, and one or more of an optical brightening agent.

In certain aspects, the disclosure relates to a method of forming an article including the steps of molding an article from the polymer composition described herein.

### DETAILED DESCRIPTION

Filled polymer compositions can have a number of improved properties based upon the type of filler added. Thermally conductive fillers may be introduced to a polymer resin matrix to impart certain thermal properties. For example, the introduction of thermally conductive fillers can facilitate heat dissipation throughout the polymer composition thereby making the composition conductive of thermal energy. The addition of white pigment or optical brightening agents to a polymer base resin can provide the composition with reflective properties. These reflective properties may make the composition particularly useful in light reflective applications, and in particular in the electronics field such as light efficiency in light emitting diodes (LEDs) and televisions. Accordingly, achieving a polymer composition that can provide both thermal conductivity as well as reflective properties proves useful. The present disclosure thus relates to a polymer composition including a polymer base resin, a thermally conductive filler, a white pigment, and an optical brightening agent, that provides dual properties of thermal conductivity and reflectivity while maintaining desirable physical properties.

In an aspect, the composition can include from about 20 wt. % to about 80 wt. % of a polymer base resin, from about 1 wt. % to about 70 wt. % of thermally conductive filler, from about 0.1 wt. % to about 50 wt. % of a white pigment, and from about 0.001 wt. % to about 10 wt. % of an optical brightening agent, wherein the polymer composition exhibits a through plane thermal conductivity of at least about 0.3 W/mK and a reflectivity of at least about 80%. The combined weight percent value of all components does not exceed about 100 wt. %, and all weight percent values are based on the total weight of the composition.

Before the present compounds, compositions, articles, systems, devices, and/or methods are disclosed and described, it is to be understood that they are not limited to specific synthetic methods unless otherwise specified, or to particular reagents unless otherwise specified, as such can, of course, vary. It is also to be understood that the terminology used herein is for the purpose of describing particular aspects only and is not intended to be limiting.

Various combinations of elements of this disclosure are encompassed by this disclosure, e.g., combinations of elements from dependent claims that depend upon the same independent claim.

Moreover, it is to be understood that unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; and the number or type of embodiments described in the specification.

All publications mentioned herein are incorporated herein by reference to disclose and describe the methods and/or materials in connection with which the publications are cited.

### Definitions

It is also to be understood that the terminology used herein is for the purpose of describing particular aspects only and is not intended to be limiting. As used in the specification and in the claims, the term “comprising” can include the embodiments “consisting of” and “consisting essentially of” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural referents unless the context clearly dictates otherwise. Thus, for example, reference to “a polycarbonate” includes mixtures of two or more polycarbonate polymers.

As used herein, the term “combination” is inclusive of blends, mixtures, alloys, reaction products, and the like.

Ranges can be expressed herein as from one value (first value) to another value (second value). When such a range is expressed, the range includes in some aspects one or both of the first value and the second value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the designated value, approximately the designated value, or about the same as the designated value. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

As used herein, the terms “optional” or “optionally” means that the subsequently described event or circumstance can or cannot occur, and that the description includes instances where said event or circumstance occurs and instances where it does not. For example, the phrase “optional additives” means that the additives can or cannot be included and that the description includes polymer compositions that both include and that do not include additional additives.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C—F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

References in the specification and concluding claims to parts by weight of a particular element or component in a composition or article, denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent of a component, unless specifically stated to the contrary, is based on the total weight of the formulation or composition in which the component is included.

As used herein the terms “weight percent,” “wt %,” and “wt. %,” which can be used interchangeably, indicate the percent by weight of a given component based on the total weight of the composition, unless otherwise specified. That is, unless otherwise specified, all wt % values are based on the total weight of the composition. It should be understood that the sum of wt % values for all components in a disclosed composition or formulation are equal to 100.

Unless otherwise stated to the contrary herein, all test standards are the most recent standard in effect at the time of filing this application.

Each of the materials disclosed herein are either commercially available and/or the methods for the production thereof are known to those of skill in the art.

It is understood that the compositions disclosed herein have certain functions. Disclosed herein are certain structural requirements for performing the disclosed functions and it is understood that there are a variety of structures that can perform the same function that are related to the disclosed structures, and that these structures will typically achieve the same result.

### Polymer Base Resin

In an aspect, the polymer composition can include a polymer base resin. In various aspects, the polymer base resin can include a thermoplastic resin or a thermoset resin. The thermoplastic resin can include polypropylene, polyethylene, ethylene based copolymer, polyamide, polycarbonate, polyester, polyoxymethylene (POM), polybutylene terephthalate (PBT), polyethylene terephthalate (PET), polycyclohexylendimethylene terephthalate (PCT), liquid crystal polymers (LPC), polyphenylene sulfide (PPS), polyphenylene ether (PPE), polyphenylene oxide-polystyrene blends, polystyrene, high impact modified polystyrene, acrylonitrile-butadiene-styrene (ABS) terpolymer, acrylic polymer, polyetherimide (PEI), polyurethane, polyetheretherketone (PEEK), polylactic acid (PLA) based polymers, poly ether sulphone (PES), and combinations thereof. The thermoplastic resin can also include thermoplastic elastomers such as polyamide and polyester based elastomers. The base substrate can also include blends and/or other types of combination of resins described above. In various aspects, the polymer base resin can also include a thermosetting polymer. Appropriate thermosetting resins can include phenol resin, urea resin, melamine-formaldehyde resin, urea-formaldehyde latex, xylene resin, diallyl phthalate resin, epoxy resin, aniline resin, furan resin, polyurethane, or combinations thereof.

The polymer base resin of the present disclosure may include a polyamide resin, or a combination of polyamide resins. Polyamide resins useful in the practice of the present disclosure include a generic family of resins referred to as nylons, which may be characterized by the presence of an amide group (—C(O)NH—). Polyamides, including also polyphthalamides (PPA), suitable for use in the present method include but are not limited to polyamide-6, polyamide-6,6, polyamide-4,6, polyamide 9T, polyamide 10T, polyamide-11, polyamide-12, polyamide-6,10, polyamide-6,12, polyamide 6/6,6, polyamide-6/6,12, polyamide MXD6, polyamide-6T, polyamide-61, polyamide-6/6T, polyamide-6/61, polyamide-6, 6/6T, polyamide-6,6/61, polyamide-6/6/1761, polyamide-6,6/6T/61, polyamide-6/12/6T, polyamide-6,6/12/6T, polyamide-6/12/61, polyamide-6,6/12/61, and combinations thereof. Nylon-6 and nylon-6,6 represent common polyamides and are available from a variety of commercial sources. Polyamides, however, such as nylon-4,6, nylon-12, nylon-6,10, nylon 6,9, nylon 6/6T and nylon 6,6/6T having triamine contents below about 0.5 wt. %, as well as others, such as amorphous nylons may also be useful.

Polyamides can be obtained by a number of well-known processes such as those described in U.S. Pat. Nos. 2,071,250, 2,071,251, 2,130,523, 2,130,948, 2,241,322, 2,312,966, and 2,512,606, the disclosures of which are incorporated by this reference in their entirety. Nylon-6, for example, is a polymerization product of caprolactam. Nylon-6,6 is a condensation product of adipic acid and 1,6-diaminohexane. Likewise, nylon 4,6 is a condensation product between adipic acid and 1,4-diaminobutane. Besides adipic acid, other useful diacids for the preparation of nylons include azelaic acid, sebacic acid, dodecane diacid, as well as terephthalic and isophthalic acids, and the like. Other useful diamines include m-xylyene diamine, di-(4-aminophenyl)methane, di-(4-aminocyclohexyl)methane; 2,2-di-(4-aminophenyl)propane, 2,2-di-(4-aminocyclohexyl)propane, among others. Copolymers of caprolactam with diacids and diamines are also useful. Mixtures of various polyamides, as well as various polyamide copolymers, are also useful. In certain aspects, the compositions disclosed herein may include between about 20 wt. % and about 80 wt. % of a polyamide polymer, such as polyamide-6,6 (or nylon-6,6).

In some aspects, polyamides having viscosity of up to about 400 ml/g can be used, or polyamides having a viscosity of about 90 to about 350 ml/g, or polyamides having a viscosity of about 110 to about 240 ml/g, as measured in a 0.5 wt % solution in 96 wt % sulfuric acid in accordance with ISO 307.

Polycarbonates, and combinations including thereof, may also be used as the polymer base resin. As used herein, “polycarbonate” refers to an oligomer or polymer including residues of one or more dihydroxy compounds, e.g., dihydroxy aromatic compounds, joined by carbonate linkages; it also encompasses homopolycarbonates, copolycarbonates, and (co)polyester carbonates. The terms “residues” and “structural units”, used in reference to the constituents of the polymers, are synonymous throughout the specification.

In certain aspects the polycarbonate polymer is a Bisphenol-A polycarbonate, a high molecular weight (Mw) high flow/ductile (HFD) polycarbonate, a low Mw HFD polycarbonate, or a combination thereof.

The terms “BisA,” “BPA,” or “bisphenol A,” which can be used interchangeably, as used herein refers to a compound having a structure represented by formula (1):

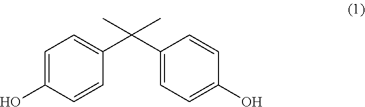 [SMILES: CC(C)(c1ccc(O)cc1)c1ccc(O)cc1]

BisA can also be referred to by the name 4,4′-(propane-2,2-diyl)diphenol; p,p′-isopropylidenebisphenol; or 2,2-bis(4-hydroxyphenyl)propane. BisA has the CAS #80-05-7.

In addition to the polycarbonates described above, combinations of the polycarbonate with other thermoplastic polymers, for example combinations of homopolycarbonates, copolycarbonates, and polycarbonate copolymers with polyesters, can be used. Useful polyesters include, for example, poly(alkylene dicarboxylates), liquid crystalline polyesters, and polyester copolymers. The polyesters described herein can generally be completely miscible with the polycarbonates when blended.

Useful polyesters can include aromatic polyesters, poly(alkylene esters) including poly(alkylene arylates), and poly(cycloalkylene diesters). In an aspect, useful aromatic polyesters can include poly(isophthalate-terephthalate-resorcinol) esters, poly(isophthalate-terephthalate-bisphenol A) esters, poly[(isophthalate-terephthalate-resorcinol) ester-co-(isophthalate-terephthalate-bisphenol A)]ester, or a combination including at least one of these. Also contemplated are aromatic polyesters with a minor amount, e.g., 0.5 to 10 wt. %, based on the total weight of the polyester, of units derived from an aliphatic diacid and/or an aliphatic polyol to make copolyesters. Examples of poly(alkylene terephthalates) include poly(ethylene terephthalate) (PET), poly(1,4-butylene terephthalate) (PBT), and poly(n-propylene terephthalate) (PPT). Also useful are poly(alkylene naphthoates), such as poly(ethylene naphthanoate) (PEN), and poly(butylene naphthanoate) (PBN). A specifically useful poly(cycloalkylene diester) is poly(1,4-cyclohexanedimethylene terephthalate) (PCT). Combinations including at least one of the foregoing polyesters can also be used.

Copolymers including alkylene terephthalate repeating ester units with other ester groups can also be useful. Specifically useful ester units can include different alkylene terephthalate units, which can be present in the polymer chain as individual units, or as blocks of poly(alkylene terephthalates). Copolymers of this type include poly(cyclohexanedimethylene terephthalate)-co-poly(ethylene terephthalate), abbreviated as PETG where the polymer includes greater than or equal to 50 mol % of poly(ethylene terephthalate), and abbreviated as PCTG where the polymer includes greater than 50 mol % of poly(1,4-cyclohexanedimethylene terephthalate).

Poly(cycloalkylene diester)s can also include poly(alkylene cyclohexanedicarboxylate)s. Of these, a specific example is poly(1,4-cyclohexane-dimethanol-1,4-cyclohexanedicarboxylate) (PCCD).

The polymer base resin can further include a polysiloxane-polycarbonate copolymer, also referred to as a poly(siloxane-carbonate). The polydiorganosiloxane (also referred to herein as “polysiloxane”) blocks include repeating diorganosiloxane units as in formula (2)

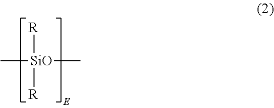

wherein each R is independently a C₁₋₁₃ monovalent organic group. For example, R can be a C₁-C₁₃ alkyl, C₁-C₁₃ alkoxy, C₂-C₁₃ alkenyl, C₂-C₁₃ alkenyloxy, C₃-C₆ cycloalkyl, C₃-C₆ cycloalkoxy, C₆-C₁₄ aryl, C₆-C₁₀ aryloxy, C₇-C₁₃ arylalkyl, C₇-C₁₃ aralkoxy, C₇-C₁₃ alkylaryl, or C₇-C₁₃ alkylaryloxy. The foregoing groups can be fully or partially halogenated with fluorine, chlorine, bromine, or iodine, or a combination thereof. In an aspect, where a transparent polysiloxane-polycarbonate is desired, R is unsubstituted by halogen. Combinations of the foregoing R groups can be used in the same copolymer.

A combination of a first and a second (or more) polycarbonate-polysiloxane copolymers can be used, wherein the average value of E of the first copolymer is less than the average value of E of the second copolymer.

In an aspect, the polydiorganosiloxane blocks are of formula (3)

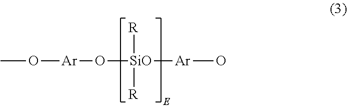

wherein E is as defined above; each R can be the same or different, and is as defined above; and Ar can be the same or different, and is a substituted or unsubstituted C₆-C₃₀ arylene, wherein the bonds are directly connected to an aromatic moiety. Ar groups in formula (3) can be derived from a C₆-C₃₀ dihydroxyarylene compound, for example a dihydroxyarylene compound. Dihydroxyarylene compounds are 1,1-bis(4-hydroxyphenyl) methane, 1,1-bis(4-hydroxyphenyl) ethane, 2,2-bis(4-hydroxyphenyl) propane, 2,2-bis(4-hydroxyphenyl) butane, 2,2-bis(4-hydroxyphenyl) octane, 1,1-bis(4-hydroxyphenyl) propane, 1,1-bis(4-hydroxyphenyl) n-butane, 2,2-bis(4-hydroxy-1-methylphenyl) propane, 1,1-bis(4-hydroxyphenyl) cyclohexane, bis(4-hydroxyphenyl sulfide), and 1,1-bis(4-hydroxy-t-butylphenyl) propane. Combinations including at least one of the foregoing dihydroxy compounds can also be used.

In another aspect, polydiorganosiloxane blocks can be of formula (4)

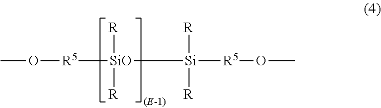

wherein R and E are as described above, and each R⁵ is independently a divalent C₁-C₃₀ organic group, and wherein the polymerized polysiloxane unit is the reaction residue of its corresponding dihydroxy compound. In one aspect, the polydiorganosiloxane blocks are of formula (5):

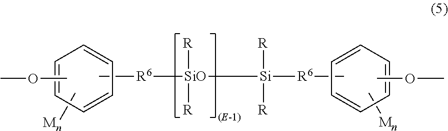

wherein R and E are as defined above. R⁶ in formula (5) is a divalent C₂-C₈ aliphatic. Each M in formula (5) can be the same or different, and can be a halogen, cyano, nitro, C₁-C₈ alkylthio, C₁-C₈ alkyl, C₁-C₈ alkoxy, C₂-C₈ alkenyl, C₂-C₈ alkenyloxy, C₃-C₈ cycloalkyl, C₃-C₈ cycloalkoxy, C₆-C₁₀ aryl, C₆-C₁₀ aryloxy, C₇-C₁₂ aralkyl, C₇-C₁₂ aralkoxy, C₇-C₁₂ alkylaryl, or C₇-C₁₂ alkylaryloxy, wherein each n is independently 0, 1, 2, 3, or 4.

In an aspect, M is bromo or chloro, an alkyl such as methyl, ethyl, or propyl, an alkoxy such as methoxy, ethoxy, or propoxy, or an aryl such as phenyl, chlorophenyl, or tolyl; R⁶ is a dimethylene, trimethylene or tetramethylene; and R is a C₁₋₈ alkyl, haloalkyl such as trifluoropropyl, cyanoalkyl, or aryl such as phenyl, chlorophenyl or tolyl. In another aspect, R is methyl, or a combination of methyl and trifluoropropyl, or a combination of methyl and phenyl. In still another aspect, R is methyl, M is methoxy, n is one, R⁶ is a divalent C₁-C₃ aliphatic group. Specific polydiorganosiloxane blocks are of the formula

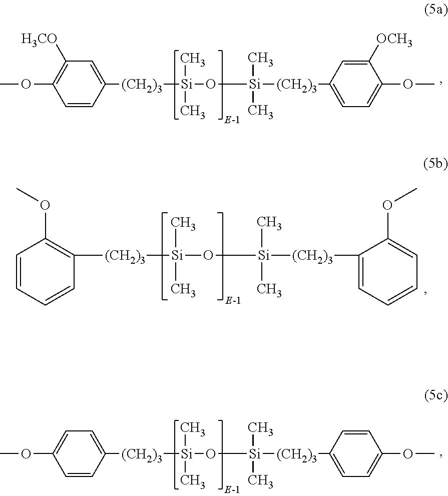

or a combination including at least one of the foregoing, wherein E has an average value of 2 to 200, 2 to 125, 5 to 125, 5 to 100, 5 to 50, 20 to 80, or 5 to 20.

Blocks of formula (5) can be derived from the corresponding dihydroxy polydiorganosiloxane, which in turn can be prepared effecting a platinum-catalyzed addition between the siloxane hydride and an aliphatically unsaturated monohydric phenol such as eugenol, 2-alkylphenol, 4-allyl-2-methylphenol, 4-allyl-2-phenylphenol, 4-allyl-2-bromophenol, 4-allyl-2-t-butoxyphenol, 4-phenyl-2-phenylphenol, 2-methyl-4-propylphenol, 2-allyl-4,6-dimethylphenol, 2-allyl-4-bromo-6-methylphenol, 2-allyl-6-methoxy-4-methylphenol and 2-allyl-4,6-dimethylphenol. The polysiloxane-polycarbonate copolymers can then be manufactured, for example, by the synthetic procedure of European Patent Application Publication No. 0 524 731 A1 of Hoover, page 5, Preparation 2.

Transparent polysiloxane-polycarbonate copolymers can include carbonate units (1) derived from bisphenol A, and repeating siloxane units (6a), (6b), (6c), or a combination including at least one of the foregoing (specifically of formula 5a), wherein E has an average value of 4 to 50, 4 to 15, specifically 5 to 15, more specifically 6 to 15, and still more specifically 7 to 10. The transparent copolymers can be manufactured using one or both of the tube reactor processes described in U.S. Patent Application No. 2004/0039145A1 or the process described in U.S. Pat. No. 6,723,864 can be used to synthesize the poly(siloxane-carbonate) copolymers.

The polysiloxane-polycarbonate copolymers can include 50 wt. % to 99 wt. % of carbonate units and 1 wt. % to 50 wt. % siloxane units. Within this range, the polyorganosiloxane-polycarbonate copolymer can include 70 wt. %, to 98 wt. %, more specifically 75 wt. % to 97 wt. % of carbonate units and 2 wt. % to 30 wt. %, more specifically 3 wt. % to 25 wt. % siloxane units.

In some aspects, a blend can be used, in particular a blend of a bisphenol A homopolycarbonate and a polysiloxane-polycarbonate block copolymer of bisphenol A blocks and eugenol capped polydimethylsilioxane blocks, of the formula (6) (formula continued onto two lines for ease of viewing):

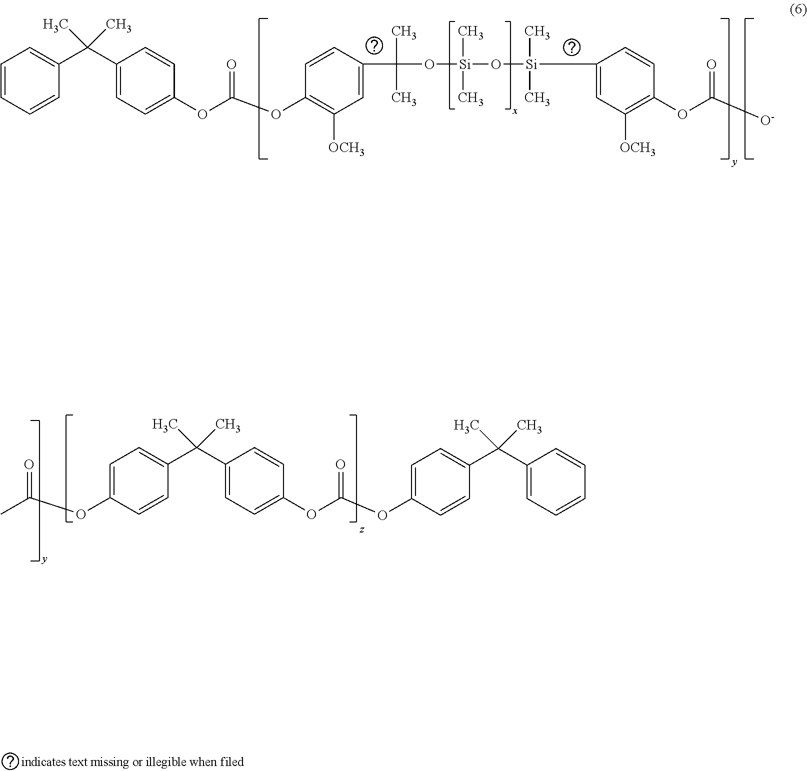

wherein x is 1 to 200, specifically 5 to 85, specifically 10 to 70, specifically 15 to 65, and more specifically 40 to 60; x is 1 to 500, or 10 to 200, and z is 1 to 1000, or 10 to 800. In an aspect, x is 1 to 200, y is 1 to 90 and z is 1 to 600, and in another aspect, x is 30 to 50, y is 10 to 30 and z is 45 to 600. The polysiloxane blocks may be randomly distributed or controlled distributed among the polycarbonate blocks.

In one aspect, the polysiloxane-polycarbonate copolymer can include 10 wt % or less, specifically 6 wt % or less, and more specifically 4 wt % or less, of the polysiloxane based on the total weight of the polysiloxane-polycarbonate copolymer, and can generally be optically transparent and are commercially available under the designation EXL-T from SABIC. In another aspect, the polysiloxane-polycarbonate copolymer can include 10 wt % or more, specifically 12 wt % or more, and more specifically 14 wt % or more, of the polysiloxane copolymer based on the total weight of the polysiloxane-polycarbonate copolymer, are generally optically opaque and are commercially available under the trade designation EXL-P from SABIC.

Polyorganosiloxane-polycarbonates can have a weight average molecular weight of 2,000 Daltons to 100,000 Daltons, specifically 5,000 to 50,000 Daltons as measured by gel permeation chromatography using a crosslinked styrene-divinyl benzene column, at a sample concentration of 1 milligram per milliliter, and as calibrated with polycarbonate standards.

The polyorganosiloxane-polycarbonates can have a melt volume flow rate, measured at 300 degrees Celsius (° C.) per 1.2 kilogram (kg), of 1 to 50 cubic centimeters per 10 minutes (cm³/10 min), specifically 2 to 30 cm³/10 min. Mixtures of polyorganosiloxane-polycarbonates of different flow properties can be used to achieve the overall desired flow property.

Non-limiting examples of polysiloxane-polycarbonate copolymers can include various copolymers available from SABIC. In an aspect, the polysiloxane-polycarbonate copolymer can contain 6% by weight polysiloxane content based upon the total weight of the polysiloxane-polycarbonate copolymer. In various aspects, the 6% by weight polysiloxane block copolymer can have a weight average molecular weight (Mw) of from about 23,000 to 24,000 Daltons using gel permeation chromatography with a bisphenol A polycarbonate absolute molecular weight standard. In certain aspects, the 6% weight siloxane polysiloxane-polycarbonate copolymer can have a melt volume flow rate (MVR) of about 10 cm³/10 min at 300° C./1.2 kg (see C9030T, a 6% by weight polysiloxane content copolymer available from SABIC as “transparent” EXL C9030T resin polymer). In another example, the polysiloxane-polycarbonate block can include 20% by weight polysiloxane based upon the total weight of the polysiloxane block copolymer. For example, an appropriate polysiloxane-polycarbonate copolymer can be a bisphenol A polysiloxane-polycarbonate copolymer endcapped with para-cumyl phenol (PCP) and having a 20% polysiloxane content (see C9030P, commercially available from SABIC as the “opaque” EXL C9030P). In various aspects, the weight average molecular weight of the 20% polysiloxane block copolymer can be about 29,900 Daltons to about 31,000 Daltons when tested according to a polycarbonate standard using gel permeation chromatography (GPC) on a crosslinked styrene-divinylbenzene column and calibrated to polycarbonate references using a UV-VIS detector set at 264 nanometers (nm) on 1 milligram per milliliter (mg/ml) samples eluted at a flow rate of about 1.0 ml/minute. Moreover, the 20% polysiloxane block copolymer can have a melt volume rate (MVR) at 300° C./1.2 kg of 7 cm³/10 min and can exhibit siloxane domains sized in a range of from about 5 micron to about 20 micrometers (microns, μm).

As provided herein, the polymer base resin may include polyesters resins. Polyester resins can include crystalline polyester resins such as polyester resins derived from at least one diol, and at least one dicarboxylic acid. Particular polyesters have repeating units according to structural formula (7)

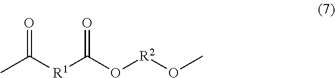

wherein, R¹ and R² are independently at each occurrence a aliphatic, aromatic and cycloaliphatic radical. In one aspect R2 is an alkyl radical compromising a dehydroxylated residue derived from an aliphatic or cycloaliphatic diol, or mixtures thereof, containing from 2 to about 20 carbon atoms and R¹ is an aromatic radical including a decarboxylated residue derived from an aromatic dicarboxylic acid. The polyester is a condensation product where R² is the residue of an aromatic, aliphatic or cycloaliphatic radical containing diol having C1 to C30 carbon atoms or chemical equivalent thereof, and R¹ is the decarboxylated residue derived from an aromatic, aliphatic or cycloaliphatic radical containing diacid of C1 to C30 carbon atoms or chemical equivalent thereof. The polyester resins are typically obtained through the condensation or ester interchange polymerization of the diol or diol equivalent component with the diacid or diacid chemical equivalent component.

Aromatic dicarboxylic acids, for example, terephthalic acid, isophthalic acid, naphthalene dicarboxylic acid and the like, can be used as these bifunctional carboxylic acids, and mixtures of these can be used as needed. Among these, terephthalic acid may be particularly suitable from the standpoint of cost. Also, to the extent that the effects of this disclosure are not lost, other bifunctional carboxylic acids such as aliphatic dicarboxylic acids such as oxalic acid, malonic acid, adipic acid, suberic acid, azelaic acid, sebacic acid, decane dicarboxylic acid, and cyclohexane dicarboxylic acid; and their ester-modified derivatives can also be used.

In an aspect, commonly used diols can be used herein without difficulty, for example, straight chain aliphatic and cycloaliphatic diols having 2 to 15 carbon atoms, for further example, ethylene glycol, propylene glycol, 1,4-butanediol, trimethylene glycol, tetramethylene glycol, neopentyl glycol, diethylene glycol, cyclohexane dimethanol, heptane-1,7-diol, octane-1,8-diol, neopentyl glycol, decane-1,10-diol, etc.; polyethylene glycol; bivalent phenols such as dihydroxydiarylalkanes such as 2,2-bis(4-hydroxylphenyl)propane that can be called bisphenol-A, bis(4-hydroxyphenyl) methane, and 2,2-bis(4-hydroxyphenyl)-1,1,1,3,3,3-hexafluoropropane, for example; dihyroxydiarylcycloalkanes such as 1,1-bis(4-hydroxyphenyl)cyclohexane, 1,1-bis(3,5-dichloro-4-hydroxyphenyl)cyclohexane, and 1,1-bis(4-hydroxyphenyl)cyclodecane; dihydroxydiarylsulfones such as bis(4-hydroxyphenyl)sulfone, and bis(3,5-dimethyl-4-hydroxyphenyl)sulfone, bis(3-chloro-4-hydroxyphenyl)sulfone; dihydroxydiarylethers such as bis(4-hydroxyphenyl)ether, and bis(3-5-dimethyl-4-hydroxyphenyl)ether; dihydroxydiaryl ketones such as 4,4′-dihydroxybenzophenone, and 3,3′,5,5′-tetramethyl-4,4-diydroxybenzophenone; dihydroxydiaryl sulfides such as bis(4-hydroxyphenyl)sulfide, bis(3-methyl-4-hydroxyphenyl)sulfide, and bis(3,5-dimethyl-4-hydroxyphenyOsulfide; dihydroxydiaryl sulfoxides such as bis(4-hydroxyphenyl)sulfoxide; dihydroxydiphenyls such as 4,4′-dihydroxyphenyl; dihydroxyarylfluorenes such as 9,9-bis(4-hydroxyphenyl)fluorene; dihydroxybenzenes such as hydroxyquinone, resorcinol, and methylhydroxyquinone; and dihydroxynaphthalenes such as 1,5-dihydroxynaphthalene and 2,6-dihydroxynaphthalene. Also, two or more kinds of diols can be combined as needed.

In a specific aspect, the polyester can be polyethylene terephthalate, polybutylene terephthalate, polyethylene naphthalate, polybutylene naphthalate, polytrimethylene terephthalate, poly(1,4-cyclohexylenedimethylene 1,4-cyclohexanedicarboxylate), poly(1,4-cyclohexylenedimethylene terephthalate), poly(cyclohexylenedimethylene-co-ethylene terephthalate), or a combination including at least one of the foregoing polyesters. Polyethylene terephthalate (PET) and polybutylene terephthalate (PBT) are particularly suitable as polyesters that are obtained by the polymerization of these kinds of bifunctional carboxylic acid and diol ingredients.

Polymer base resin compositions of the present disclosure can be a single kind of polyester used alone, or two or more kinds used in combination. Furthermore, copolyesters can also be used as needed.

In an aspect, polyetherimides can be used in the disclosed compositions and can be of formula (8):

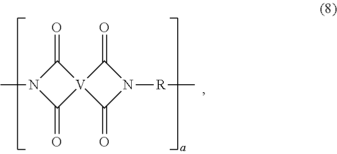

wherein a is more than 1, for example 10 to 1,000 or more, or more specifically 10 to 500.

The group V in formula (8) is a tetravalent linker containing an ether group (a “polyetherimide” as used herein) or a combination of an ether groups and arylenesulfone groups (a “polyetherimidesulfone”). Such linkers include but are not limited to: (a) substituted or unsubstituted, saturated, unsaturated or aromatic monocyclic and polycyclic groups having 5 to 50 carbon atoms, optionally substituted with ether groups, arylenesulfone groups, or a combination of ether groups and arylenesulfone groups; and (b) substituted or unsubstituted, linear or branched, saturated or unsaturated alkyl groups having 1 to 30 carbon atoms and optionally substituted with ether groups or a combination of ether groups, arylenesulfone groups, and arylenesulfone groups; or combinations including at least one of the foregoing. Suitable additional substitutions include, but are not limited to, ethers, amides, esters, and combinations including at least one of the foregoing.

The R group in formula (8) can include but is not limited to substituted or unsubstituted divalent organic groups such as: (a) aromatic hydrocarbon groups having 6 to 20 carbon atoms and halogenated derivatives thereof; (b) straight or branched chain alkylene groups having 2 to 20 carbon atoms; (c) cycloalkylene groups having 3 to 20 carbon atoms, or (d) divalent groups of formula (9):

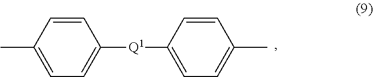

wherein Q1 includes but is not limited to a divalent moiety such as —O—, —S—, —C(O)—, —SO₂—, —SO—, —C_{y}H_{2y}— (y being an integer from 1 to 5), and halogenated derivatives thereof, including perfluoroalkylene groups.

In an aspect, linkers V can include but are not limited to tetravalent aromatic groups of formula (10):

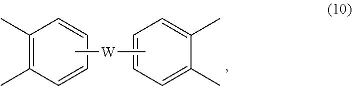

wherein W is a divalent moiety including —O—, —SO₂—, or a group of the formula —O—Z—O— wherein the divalent bonds of the —O— or the —O—Z—O— group are in the 3,3′, 3,4′, 4,3′, or the 4,4′ positions, and wherein Z includes, but is not limited, to divalent groups of formulas (11):

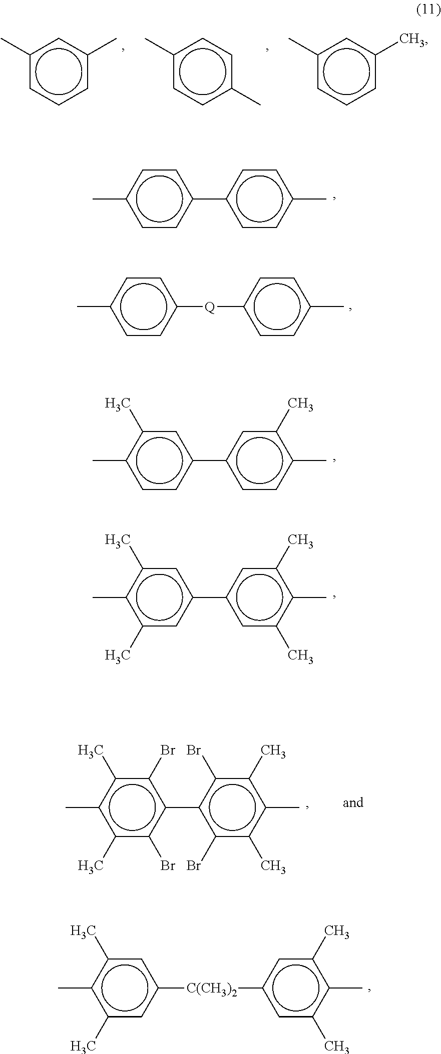

wherein Q can include, but is not limited to a divalent moiety including —O—, —S—, —C(O), —SO₂—, —SO—, —C_{y}H_{2y}— (y being an integer from 1 to 5), and halogenated derivatives thereof, including perfluoroalkylene groups.

In an aspect, the polyetherimide include more than 1, specifically 10 to 1,000, or more specifically, 10 to 500 structural units, of formula (12):

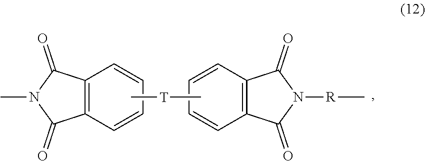

wherein T is —O— or a group of the formula —O—Z—O— wherein the divalent bonds of the —O— or the —O—Z—O— group are in the 3,3′, 3,4′, 4,3′, or the 4,4′ positions; Z is a divalent group of formula (8) as defined above; and R is a divalent group of formula (8) as defined above.

In another aspect, the polyetherimidesulfones can be polyetherimides including ether groups and sulfone groups.

Even more specifically, polyetherimidesulfones can include more than 1, specifically 10 to 1,000, or more specifically, 10 to 500 structural units of formula (13):

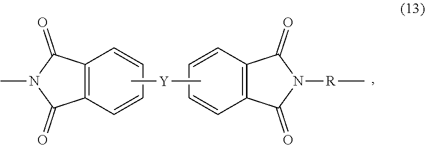

wherein Y is —O—, —SO₂—, or a group of the formula —O—Z—O— wherein the divalent bonds of the —O—, SO₂—, or the —O—Z—O— group are in the 3,3′, 3,4′, 4,3′, or the 4,4′ positions, wherein Z is a divalent group of formula (8) as defined above and R is a divalent group of formula (6) as defined above, provided that greater than 50 mole % of the sum of moles Y+moles R in formula (6) contain —SO₂— groups.

It is to be understood that the polyetherimides and polyetherimidesulfones can optionally include linkers V that do not contain ether or ether and sulfone groups, for example linkers of formula (14):

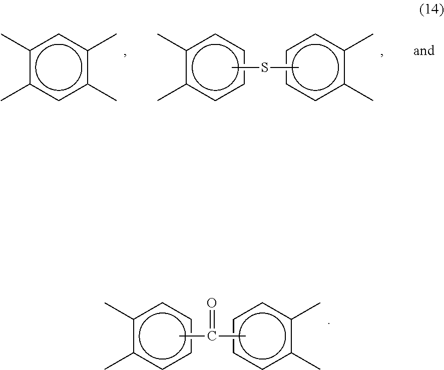

Imide units containing such linkers can generally be present in amounts ranging from 0 to 10 mole % of the total number of units, specifically 0 to 5 mole %. In one aspect no additional linkers V are present in the polyetherimides and polyetherimidesulfones.

The polyetherimide resin can be selected from the group consisting of a polyetherimide, for example, as described in U.S. Pat. Nos. 3,875,116, 6,919,422, and 6,355,723; a silicone polyetherimide, for example, as described in U.S. Pat. Nos. 4,690,997 and 4,808,686; a polyetherimidesulfone resin, as described in U.S. Pat. No. 7,041,773; or combinations thereof. Each of these publications is incorporated by this reference in its entirety.

In one aspect, the polymer base resin can include a polyamide polymer. In a further aspect, the polyamide polymer component can include a single polyamide or, alternatively, in another aspect can include a blend of two or more different polyamides. In one aspect, the polyamide polymer component can be nylon 6.

As noted herein, the polymer base resin can include a number of thermoplastic resins, or a combination thereof. In one example, the polymer base resin can include a polycarbonate copolymer including units derived from BPA, or a mixture of one or more polycarbonate copolymers including units derived from BPA. In a specific example, the polymer base resin can include a polycarbonate copolymer having units derived from BPA and a poly(aliphatic ester)-polycarbonate copolymer derived from sebacic acid.

In further examples, a polycarbonate of the polymer base resin can include a branched polycarbonate. An exemplary branching agent can include, but is not limited to 1,1,1-tris(4-hydroxyphenyl)ethane (THPE). As a further example, the branched polycarbonate resin may be endcapped with an appropriate end-capping agent, such as for example, p-cyanolphenol (known as HBN).

Certain aspects of the composition include from about 20 wt. % to about 80 wt. % of a polymer base resin. In further aspects, the composition includes from about 20 wt. % to about 80 wt. % of a polymer base resin, or from about 30 wt. % to about 50 wt. % of a polymer base resin, or from about 30 wt. % to about 45 wt. % of a polymer base resin.

### Thermally Conductive Filler

In various aspects, the composition can include a thermally conductive filler.

Exemplary thermally conductive fillers include white thermally conductive fillers, which include, but are not limited to, ZnS (zinc sulfide), CaO (calcium oxide), MgO (magnesium oxide), ZnO (zinc oxide), or TiO₂ (titanium dioxide), tin dioxide, chromium Oxide, CaCO₃ (calcium carbonate), mica, BaO (barium oxide), BaSO₄ (barium sulfate), CaSO₄ (calcium sulfate), CaSiO₃ (wollastonite), ZrO₂ (Zirconium oxide), SiO₂ (Silicon oxide), Glass beads, Glass fiber, MgO.xAl₂O₃ (magnesium aluminate), CaMg(CO₃)₂ (dolomite), coated graphite, Mg(OH)₂ (magnesium hydroxide), H₂Mg₃(SiO₃)₄ (talc), γ-AlO(OH) (boehmite), α-AlO(OH) (diaspore), Al(OH)₃ (Gibbsite), clay; AlN (aluminum nitride), Al₄C₃ (aluminum carbide), Al₂O₃ (aluminum oxide), BN (boron nitride), AlON (aluminum oxynitride), MgSiN₂ (magnesium silicon nitride), SiC (silicon carbide), Si₃N₄ (silicon nitride), tungsten oxide, aluminum phosphide, beryllium oxide, boron phosphide, cadmium sulfide, gallium nitride, zinc silicate, and WO₃, dark color thermally conductive fillers with certain white coating, which include graphite, expanded graphite, expandable graphite, graphene, carbon fiber, CNT (carbon nano-tube); or a combination thereof. In some aspects, the thermally conductive filler may have a thermal conductivity of greater than 5 watts per meter kelvin (W/m*K).

In some aspects, the composition can include a thermally conductive filler having a certain particle size and/or surface area. As an example, the thermally conductive filler may have a particle size distribution D50 between 100 nanometers (nm) and 500 micrometers (μm). In a further example, the suitable thermally conductive fillers may have a surface area between 0.1 square meters per gram (m²/g) and 2000 m²/g.

In various further aspects, the thermally conductive filler may have a particular shape. For example, the thermally conductive filler may include spheres or beads, blocks, flakes, fibers, whisker, needle-like shapes or a combination thereof. The thermally conductive filler may have any dimensionality, including 1D, 2D and 3D geometries.

In some aspects, the composition can include from about 1 wt. % to about 70 wt. % of a thermally conductive filler. In further aspects the composition may include from about 20 wt. % to about 70 wt. % of a thermally conductive filler, or from about 35 wt. % to about 70 wt. % of a thermally conductive filler, or from about 50 wt. % to about 70 wt. % of a thermally conductive filler.

### White Pigment

In addition to the polymer base resin and thermally conductive filler, the polymer composition of the present disclosure may also include a white pigment. The white pigment can impart the polymer resin composition with opacity or a bright opaque appearance. In further aspects, the white pigment can impart the polymer resin composition with a white or off-white color. Further, these pigments tend to possess high reflectivity to both near infrared (NIR) and visible light. As used herein, reflectivity can refer to the ability to scatter light away from the surface of the material without absorbing the light at a given wavelength.

Exemplary white pigments can include titanium dioxide, zinc sulfide (ZnS), tin oxide, aluminum oxide (AlO₃), zinc oxide (ZnO), calcium sulfate, barium sulfate (BaSO₄), calcium carbonate (e.g., chalk), magnesium carbonate, antimony oxide (Sb₂O₃), white lead (a basic lead carbonate, 2PbCO₃.Pb(OH)₂), lithopone (a combination of barium sulfate and zinc sulfide), sodium silicate, aluminum silicate, silicon dioxide (SiO₂, i.e., silica), mica, clay, talc, metal doped versions of the foregoing materials, and combinations including at least one of the foregoing materials. More particularly, the inorganic white pigment is selected from rutile or anatase titanium dioxide, zinc sulfide, and coated versions thereof such as silanized titanium dioxide. A combination of different types of white pigment can be used. In particular aspects, the white pigment can include titanium dioxide, antimony oxide, zinc oxide, white lead, or lithopone. In some aspects of the present disclosure, talc may be used as a white pigment. Talc may be a suitable white pigment where the material has a sufficiently high color coordinate value to lend the material a white color. In one example, talc having a value of the color coordinate *L (corresponding to the whiteness of a given material) that is greater than 80 would be an appropriate white pigment as described herein.

The white pigment can have an average particle size of 0.01 to 10 micrometers (μm), specifically 0.05 μm to 1 μm, and more particularly 0.1 μm to 0.6 μm. The white pigment can be present in an amount of from about 0.1 wt. % to about 50 wt. %. As an example, the composition may include titanium dioxide in an amount of between 0.1 wt. % and 50 wt. %. In a further example, the composition may include titanium dioxide in an amount between 0.1 wt. % and 20 wt. %.

### Optical Agent

In further aspects of the present disclosure, the polymer compositions can include an optical agent. The optical agent may include an optical brightener. Examples of optical brighteners include optical brightening agents (OBAs), fluorescent brightening agents (FBAs), fluorescent whitening agents (FWAs), or the like, or a combination including at least one of the foregoing optical brighteners. As used herein, optical brighteners refer to dyes absorbing light in the ultraviolet and violet region (usually about 340 to about 370 nm) of the electromagnetic spectrum, and re-emit light in the blue region (usually about 420 to about 470 nm). These additives are often used to enhance the appearance of color of a polymer composition, causing a perceived “whitening” effect. According to the perceived whitening effect, a given material can appear less yellow by increasing the overall amount of blue light reflected. Exemplary optical brighteners are triazine-stilbenes (di-, tetra- or hexa-sulfonated), coumarins, imidazolines, diazoles, triazoles, benzoxazolines, biphenyl-stilbenes, or the like or a combination including at least one of the foregoing optical brighteners. In particular aspects of the present disclosure, the optical agent may include, but is not limited to, 4,4′-bis(2-benzoxazolyl)stilbene, available commercially as Eastman Eastobrite™ OB-1, or 2,5-bis(5-tert-butyl-2-benzoxazolyl)thiophene, available commercial Tinopal™ OB, as or a combination thereof.

In certain aspects the composition includes from about 0.001 wt. % to about 10 wt. % of an optical brightening agent. In further aspects the composition includes from about 0.01 wt. % to about 5 wt. % of an optical brightening agent, or from about 0.01 wt. % to about 1 wt. % of an optical brightening agent.

### Additives

The disclosed thermoplastic composition can include one or more additives conventionally used in the manufacture of molded thermoplastic parts with the proviso that the optional additives do not adversely affect the desired properties of the resulting composition. Mixtures of optional additives can also be used. Such additives can be mixed at a suitable time during the mixing of the components for forming the composite mixture. Exemplary additives can include ultraviolet agents, ultraviolet stabilizers, heat stabilizers, antistatic agents, anti-microbial agents, anti-drip agents, radiation stabilizers, pigments, dyes, fibers, fillers, plasticizers, fibers, flame retardants, antioxidants, lubricants, wood, glass, and metals, and combinations thereof.

The thermoplastic composition disclosed herein can include one or more additional fillers. The filler can be selected to impart additional impact strength and/or provide additional characteristics that can be based on the final selected characteristics of the polymer composition. In some aspects, the filler(s) can include inorganic materials which can include clay, titanium oxide, asbestos fibers, silicates and silica powders, boron powders, calcium carbonates, talc, kaolin, sulfides, barium compounds, metals and metal oxides, wollastonite, glass spheres, glass fibers, flaked fillers, fibrous fillers, natural fillers and reinforcements, and reinforcing organic fibrous fillers.

Appropriate fillers or reinforcing agents can include, for example, mica, clay, feldspar, quartz, quartzite, perlite, tripoli, diatomaceous earth, aluminum silicate (mullite), synthetic calcium silicate, fused silica, fumed silica, sand, boron-nitride powder, boron-silicate powder, calcium sulfate, calcium carbonates (such as chalk, limestone, marble, and synthetic precipitated calcium carbonates) talc (including fibrous, modular, needle shaped, and lamellar talc), wollastonite, hollow or solid glass spheres, silicate spheres, cenospheres, aluminosilicate or (armospheres), kaolin, whiskers of silicon carbide, alumina, boron carbide, iron, nickel, or copper, continuous and chopped carbon fibers or glass fibers, molybdenum sulfide, zinc sulfide, barium titanate, barium ferrite, barium sulfate, heavy spar, TiO₂, aluminum oxide, magnesium oxide, particulate or fibrous aluminum, bronze, zinc, copper, or nickel, glass flakes, flaked silicon carbide, flaked aluminum diboride, flaked aluminum, steel flakes, natural fillers such as wood flour, fibrous cellulose, cotton, sisal, jute, starch, lignin, ground nut shells, or rice grain husks, reinforcing organic fibrous fillers such as poly(ether ketone), polyimide, polybenzoxazole, poly(phenylene sulfide), polyesters, polyethylene, aromatic polyamides, aromatic polyimides, polyetherimides, polytetrafluoroethylene, and poly(vinyl alcohol), as well combinations including at least one of the foregoing fillers or reinforcing agents. The fillers and reinforcing agents can be coated with a layer of metallic material to facilitate conductivity, or surface treated, with silanes for example, to improve adhesion and dispersion with the polymer matrix. Fillers generally can be used in amounts of 1 to 200 parts by weight, based on 100 parts by weight of the total composition.

In some aspects, the thermoplastic composition may include a synergist. In various examples fillers may serve as flame retardant synergists. The synergist facilitates an improvement in the flame retardant properties when added to the flame retardant composition over a comparative composition that contains all of the same ingredients in the same quantities except for the synergist. Examples of mineral fillers that may serve as synergists are mica, talc, calcium carbonate, dolomite, wollastonite, barium sulfate, silica, kaolin, feldspar, barytes, or the like, or a combination including at least one of the foregoing mineral fillers. Metal synergists, e.g., antimony oxide, can also be used with the flame retardant. In one example, the synergist may include magnesium hydroxide and phosphoric acid. The mineral filler may have an average particle size of about 0.1 to about 20 μm, specifically about 0.5 to about 10 μm, and more specifically about 1 to about 3 μm.

The thermoplastic composition can include an antioxidant. The antioxidants can include either a primary or a secondary antioxidant. For example, antioxidants can include organophosphites such as tris(nonyl phenyl)phosphite, tris(2,4-di-t-butylphenyl)phosphite, bis(2,4-di-t-butylphenyl)pentaerythritol diphosphite, distearyl pentaerythritol diphosphite or the like; alkylated monophenols or polyphenols; alkylated reaction products of polyphenols with dienes, such as tetrakis[methylene(3,5-di-tert-butyl-4-hydroxyhydrocinnamate)]methane, or the like; butylated reaction products of para-cresol or dicyclopentadiene; alkylated hydroquinones; hydroxylated thiodiphenyl ethers; alkylidene-bisphenols; benzyl compounds; esters of beta-(3,5-di-tert-butyl-4-hydroxyphenyl)-propionic acid with monohydric or polyhydric alcohols; esters of beta-(5-tert-butyl-4-hydroxy-3-methylphenyl)-propionic acid with monohydric or polyhydric alcohols; esters of thioalkyl or thioaryl compounds such as distearylthiopropionate, dilaurylthiopropionate, ditridecylthiodipropionate, octadecyl-3-(3,5-di-tert-butyl-4-hydroxyphenyl)propionate, pentaerythrityl-tetrakis[3-(3,5-di-tert-butyl-4-hydroxyphenyl)propionate or the like; amides of beta-(3,5-di-tert-butyl-4-hydroxyphenyl)-propionic acid or the like, or combinations including at least one of the foregoing antioxidants. Antioxidants can generally be used in amounts of from 0.01 to 0.5 parts by weight, based on 100 parts by weight of the total composition, excluding any filler.

In various aspects, the thermoplastic composition can include a mold release agent. Exemplary mold releasing agents can include for example, metal stearate, stearyl stearate, pentaerythritol tetrastearate, beeswax, montan wax, paraffin wax, or the like, or combinations including at least one of the foregoing mold release agents. Mold releasing agents are generally used in amounts of from about 0.1 to about 1.0 parts by weight, based on 100 parts by weight of the total composition, excluding any filler.

In an aspect, the thermoplastic composition can include a heat stabilizer. As an example, heat stabilizers can include, for example, organo phosphites such as triphenyl phosphite, tris-(2,6-dimethylphenyl)phosphite, tris-(mixed mono- and di-nonylphenyl)phosphite or the like; phosphonates such as dimethylbenzene phosphonate or the like, phosphates such as trimethyl phosphate, or the like, or combinations including at least one of the foregoing heat stabilizers. Heat stabilizers can generally be used in amounts of from 0.01 to 0.5 parts by weight based on 100 parts by weight of the total composition, excluding any filler.

In further aspects, light stabilizers can be present in the thermoplastic composition. Exemplary light stabilizers can include, for example, benzotriazoles such as 2-(2-hydroxy-5-methylphenyl)benzotriazole, 2-(2-hydroxy-5-tert-octylphenyl)-benzotriazole and 2-hydroxy-4-n-octoxy benzophenone or the like or combinations including at least one of the foregoing light stabilizers. Light stabilizers can generally be used in amounts of from about 0.1 to about 1.0 parts by weight, based on 100 parts by weight of the total composition, excluding any filler.

The thermoplastic composition can also include plasticizers. For example, plasticizers can include phthalic acid esters such as dioctyl-4,5-epoxy-hexahydrophthalate, tris-(octoxycarbonylethyl) isocyanurate, tristearin, epoxidized soybean oil or the like, or combinations including at least one of the foregoing plasticizers. Plasticizers are generally used in amounts of from about 0.5 to about 3.0 parts by weight, based on 100 parts by weight of the total composition, excluding any filler.

In further aspects, the disclosed composition can include antistatic agents. These antistatic agents can include, for example, glycerol monostearate, sodium stearyl sulfonate, sodium dodecylbenzenesulfonate or the like, or combinations of the foregoing antistatic agents. In one aspect, carbon fibers, carbon nanofibers, carbon nanotubes, carbon black, or any combination of the foregoing can be used in a polymeric resin containing chemical antistatic agents to render the composition electrostatically dissipative.

Ultraviolet (UV) absorbers can also be present in the disclosed thermoplastic composition. Exemplary ultraviolet absorbers can include for example, hydroxybenzophenones; hydroxybenzotriazoles; hydroxybenzotriazines; cyanoacrylates; oxanilides; benzoxazinones; 2-(2H-benzotriazol-2-yl)-4-(1,1,3,3-tetramethylbutyl)-phenol (CYASORB™ 5411); 2-hydroxy-4-n-octyloxybenzophenone (CYASORB™ 531); 2-[4,6-bis(2,4-dimethylphenyl)-1,3,5-triazin-2-yl]-5-(octyloxy)-phenol (CYASORB™ 1164); 2,2′-(1,4-phenylene)bis(4H-3,1-benzoxazin-4-one) (CYASORB™ UV-3638); 1,3-bis[(2-cyano-3,3-diphenylacryloyl)oxy]-2,2-bis[[(2-cyano-3,3-diphenylacryloyl)oxy]methyl]propane (UVINUL™ 3030); 2,2′-(1,4-phenylene) bis(4H-3,1-benzoxazin-4-one); 1,3-bis[(2-cyano-3,3-diphenylacryloyl)oxy]-2,2-bis[[(2-cyano-3,3-diphenylacryloyl)oxy]methyl]propane; nano-size inorganic materials such as titanium oxide, cerium oxide, and zinc oxide, all with particle size less than 100 nanometers; or the like, or combinations including at least one of the foregoing UV absorbers. UV absorbers are generally used in amounts of from 0.01 to 3.0 parts by weight, based on 100 parts by weight of the total composition, excluding any filler.

The thermoplastic composition can further include a lubricant. As an example, lubricants can include for example, fatty acid esters such as alkyl stearyl esters, e.g., methyl stearate or the like; mixtures of methyl stearate and hydrophilic and hydrophobic surfactants including polyethylene glycol polymers, polypropylene glycol polymers, and copolymers thereof e.g., methyl stearate and polyethylene-polypropylene glycol copolymers in a suitable solvent; or combinations including at least one of the foregoing lubricants. Lubricants can generally be used in amounts of from about 0.1 to about 5 parts by weight, based on 100 parts by weight of the total composition, excluding any filler.

Anti-drip agents can also be used in the composition, for example a fibril forming or non-fibril forming fluoropolymer such as polytetrafluoroethylene (PTFE). The anti-drip agent can be encapsulated by a rigid copolymer, for example styrene-acrylonitrile copolymer (SAN). PTFE encapsulated in SAN is known as TSAN. In one example, TSAN can include 50 wt. % PTFE and 50 wt. % SAN, based on the total weight of the encapsulated fluoropolymer. The SAN can include, for example, 75 wt. % styrene and 25 wt. % acrylonitrile based on the total weight of the copolymer. An antidrip agent, such as TSAN, can be used in amounts of 0.1 to 10 parts by weight, based on 100 parts by weight of the total composition, excluding any filler.

As an example, the disclosed composition can include an impact modifier. The impact modifier can be a chemically reactive impact modifier. By definition, a chemically reactive impact modifier can have at least one reactive group such that when the impact modifier is added to a polymer composition, the impact properties of the composition (expressed in the values of the IZOD impact) are improved. In some examples, the chemically reactive impact modifier can be an ethylene copolymer with reactive functional groups selected from, but not limited to, anhydride, carboxyl, hydroxyl, and epoxy.

In further aspects of the present disclosure, the composition can include a rubbery impact modifier. The rubber impact modifier can be a polymeric material which, at room temperature, is capable of recovering substantially in shape and size after removal of a force. However, the rubbery impact modifier should typically have a glass transition temperature of less than 0° C. In certain aspects, the glass transition temperature (Tg) can be less than −5° C., −10° C., −15° C., with a Tg of less than −30° C. typically providing better performance. Representative rubbery impact modifiers can include, for example, functionalized polyolefin ethylene-acrylate terpolymers, such as ethylene-acrylic esters-maleic anhydride (MAH) or glycidyl methacrylate (GMA). The functionalized rubbery polymer can optionally contain repeat units in its backbone which are derived from an anhydride group containing monomer, such as maleic anhydride. In another scenario, the functionalized rubbery polymer can contain anhydride moieties which are grafted onto the polymer in a post polymerization step.

In one example, the composition can include a core-shell copolymer impact modifier having about 80 wt. % of a core including poly(butyl acrylate) and about 20 wt. % of a shell including poly(methyl methacrylate). In a further example, the impact modifier can include an acrylic impact modifier such as ethylene-ethylacrylate copolymer with an ethyl acrylate content of less than 20 wt. % (such as EXL 3330 as supplied by SABIC). The composition can include about 5 wt. % of the ethylene-ethylacrylate copolymer.

In many aspects, the compositions can be prepared according to a variety of methods. The compositions of the present disclosure can be blended, compounded, or otherwise combined with the aforementioned ingredients by a variety of methods involving intimate admixing of the materials with any additional additives desired in the formulation. Because of the availability of melt blending equipment in commercial polymer processing facilities, melt processing methods can be used. In various further aspects, the equipment used in such melt processing methods can include, but is not limited to, co-rotating and counter-rotating extruders, single screw extruders, co-kneaders, disc-pack processors and various other types of extrusion equipment. In a further aspect, the extruder is a twin-screw extruder. In various further aspects, the composition can be processed in an extruder at temperatures from about 180° C. to about 350° C., particularly 250° C. to 300° C.

### Properties and Articles

In certain aspects, the compositions can exhibit improved thermal conductivity and reflectivity. For example, in some aspects the compositions can exhibit a through plane thermal conductivity of at least about 0.3 W/mK when tested in accordance with ASTM E1461. In other aspects the compositions can exhibit a through plane thermal conductivity of at least about 0.3 W/mK when tested in accordance with ASTM E1461, or at least about 0.5 W/mK, or at least about 0.75 W/mK, or at least about 1.0 W/mK, or at least about 1.25 W/mK, or at least about 1.5 W/mK, or at least about 1.75 W/mK or at least about 2.0 W/mK.

In various aspects, the thermoplastic compositions can exhibit a reflectivity of at least about 80% when calculated from observed color coordinates. In further aspects the thermoplastic compositions can exhibit a reflectivity of at least about 82% when calculated from observed color coordinates, or at least about 84%, or at least about 86%, or at least about 88%, or at least about 90%, or at least about 92%, or at least about 94%, or at least about 96%.

In various aspects, the present disclosure relates to articles including the compositions herein. The compositions can be molded into useful shaped articles by a variety of means such as injection molding, extrusion, rotational molding, blow molding and thermoforming to form articles. The compositions can be useful in the manufacture of articles requiring materials with high modulus, good flow, good impact strength, thermal conductivity, and reflectivity.

The advantageous characteristics of the compositions disclosed herein can make them appropriate for an array of uses. Formed articles can include, but are not limited to, personal computers, notebook and portable computers, cell phone antennas and other such communications equipment, medical applications, RFID applications, automotive applications, and the like. In various further aspects, the article can be appropriate as a computer and business machine housing such as a housing for high end laptop personal computers, monitors, robotics, a hand held electronic device housing (such as a housing or flash holder for smart phones, tablets, music devices), electrical connectors, LED heat sink, and components of lighting fixtures, wearables, ornaments, home appliances, and the like.

In a further aspect, non-limiting examples of fields in which the thermoplastic compositions can be employed can include electrical, electro-mechanical, radio frequency (RF) technology, telecommunication, automotive, aviation, medical, sensor, military, and security. In a still further aspect, the thermoplastic compositions can also be present in overlapping fields, such as mechatronic systems that integrate mechanical and electrical properties which can, for example, be used in automotive or medical engineering.

In a further aspect, the suitable article can be an electronic device, automotive device, telecommunication device, medical device, security device, or mechatronic device. In a still further aspect, the article can be selected from a computer device, electromagnetic interference device, printed circuit, Wi-Fi device, Bluetooth device, GPS device, cellular antenna device, smart phone device, automotive device, medical device, sensor device, security device, shielding device, RF antenna device, LED device, and RFID device. In yet a further aspect, the article can be selected from a computer device, sensor device, security device, RF antenna device, LED device and RFID device.

In a further aspect, the molded articles can be used to manufacture devices in the automotive field. In a still further aspect, non-limiting examples of such devices in the automotive field which can use the disclosed blended thermoplastic compositions in the vehicle's interior include adaptive cruise control, headlight sensors, windshield wiper sensors, and door/window switches. In a further aspect, non-limiting examples of devices in the automotive field which can the disclosed blended thermoplastic compositions in the vehicle's exterior include pressure and flow sensors for engine management, air conditioning, crash detection, and exterior lighting fixtures.

In a further aspect, the resulting disclosed compositions can be used to provide any desired shaped, formed, or molded articles. For example, the disclosed compositions can be molded into useful shaped articles by a variety of means such as injection molding, extrusion, rotational molding, blow molding and thermoforming. As noted above, the disclosed compositions are particularly well suited for use in the manufacture of electronic components and devices. As such, according to some aspects, the disclosed compositions can be used to form articles such as printed circuit board carriers, burn in test sockets, flex brackets for hard disk drives, and the like.

### Aspects

Aspect 1. A polymer composition comprising: from about 20 wt. % to about 80 wt. % of a polymer base resin; from about 1 wt. % to about 70 wt. % of a thermally conductive filler; from about 0.1 wt. % to about 50 wt. % of a white pigment; and from about 0.001 wt. % to about 10 wt. % of an optical brightening agent, wherein the polymer composition exhibits a through plane thermal conductivity of at least about 0.3 W/mK and a reflectivity of at least about 80%, and wherein the combined weight percent value of all components does not exceed about 100 wt. %, and all weight percent values are based on the total weight of the polymer composition.

Aspect 2. A polymer composition comprising: from about 20 wt. % to about 60 wt. % of a polymer base resin; from about 1 wt. % to about 70 wt. % of a thermally conductive filler; from about 0.1 wt. % to about 25 wt. % of at least one white pigment; and from about 0.001 wt. % to about 10 wt. % of an optical brightening agent wherein the polymer composition exhibits a through plane thermal conductivity of at least about 0.3 W/mK and a reflectivity of at least about 90%, and wherein the combined weight percent value of all components does not exceed about 100 wt. %, and all weight percent values are based on the total weight of the polymer composition.

Aspect 3. The polymer composition of aspect 1, wherein the polymer base resin comprises a polyamide polymer or a combination of polyamide polymers.

Aspect 4. The polymer composition of any of aspects 1-3, wherein the thermally conductive filler comprises zinc sulfide, calcium oxide, magnesium oxide, zinc oxide, titanium dioxide, tin dioxide, chromium oxide, calcium carbonate, mica, barium oxide, barium sulfate, calcium sulfate, wollastonite, zirconium oxide, silicon oxide, glass beads, glass fiber, magnesium aluminate, dolomite, coated graphite, magnesium hydroxide, talc, boehmite, diaspore, gibbsite, clay; aluminum nitride, aluminum carbide, aluminum oxide, boron nitride, aluminum oxynitride, magnesium silicon nitride, silicon carbide, silicon nitride, tungsten oxide, aluminum phosphide, beryllium oxide, boron phosphide, cadmium sulfide, gallium nitride, zinc silicate, tungsten oxide or a combination thereof.

Aspect 5. The polymer composition of any of aspects 1-3, wherein the thermally conductive filler comprises one or more of magnesium hydroxide and boron nitride or a combination thereof.

Aspect 6. The polymer composition of any of aspects 1-3, wherein the thermally conductive filler has a thermal conductivity of at least about 5 W/m*K.

Aspect 7. The polymer composition of any of aspects 1-6, wherein the white pigment comprises titanium dioxide, zinc sulfate, antimony oxide, zinc oxide, a lead carbonate, lithopone, or a combination thereof.

Aspect 8. The polymer composition of any of aspects 1-6, wherein the white pigment comprises titanium dioxide.

Aspect 9. The polymer composition of any of aspects 1-6, wherein the polymer composition comprises white pigment in an amount between 1 wt. % and 10 wt. %.

Aspect 10. The polymer composition of any of aspects 1-9, wherein the optical brightening agent comprises a fluorescent optical brightening agent.

Aspect 11. The polymer composition of any of aspects 1-9, wherein the optical brightening agent comprises 4,4′-bis(2-benzoxazolyl) stilbene.

Aspect 12. The polymer composition of any of aspects 1-9, wherein the optical brightening agent comprises 2,5-bis(5-tert-butyl-2-benzoxazolyl)thiophene.

Aspect 13. The polymer composition of any of aspects 1-12, wherein the polymer composition further comprises an additive.

Aspect 14. The polymer composition of aspect 13, wherein the additive comprises a pigment, a dye, a filler, a plasticizer, a fiber, a flame retardant, an antioxidant, a lubricant, wood, glass, metal, an ultraviolet agent, an anti-static agent, an anti-microbial agent, or combinations thereof.

Aspect 15. The polymer composition of any of aspects 1-14, further comprising talc.

Aspect 16. An article comprising the polymer composition of any of aspects 1-15.

Aspect 17. The article of aspect 16, wherein the article is an LED heat sink or an electronics housing.

### Examples

Detailed aspects of the present disclosure are disclosed herein; it is to be understood that the disclosed aspects are merely exemplary of the disclosure that may be embodied in various forms. Therefore, specific structural and functional details disclosed herein are not to be interpreted as limits, but merely as a basis for teaching one skilled in the art to employ the present disclosure. The specific examples below will enable the disclosure to be better understood. However, they are given merely by way of guidance and do not imply any limitation.

The following examples are provided to illustrate the compositions, processes, and properties of the present disclosure. The examples are merely illustrative and are not intended to limit the disclosure to the materials, conditions, or process parameters set forth therein.

### General Materials and Methods

The compositions as set forth in the Examples below were prepared from the components presented in Table 1.

TABLE 1
Components of the compositions

| Component | Item code | Description | CAS# |
|---|---|---|---|
| PA1 | 83900 | Polyamide-6; PA6 Regular (Ultramid ® B27) | 25038-54-4 |
| PA2 | 83913 | PA6 (Domamid ® 24) | 25038-54-4 |
| | | (lower viscosity polyamide than PA1) | |
| Talc | F505755 | Talc GH7(05) from Hayashi Kasei | 14807-96-6 |
| TiO₂ coated | R107C | Coated Titanium dioxide (TiO₂), K2233 | 13463-67-7, |
| | | | 21645-51-2, |
| | | | 7631-86-9 |
| TiO₂ | R10834 | Titanium dioxide TiO2, (DuPont R-103) | 13463-67-7, 21645- |
| | | | 51-2, 7631-86-9 |
| BN | F534387 | Hexagonal Boron Nitride BNHN | 10043-11-5 |
| Mg(OH)₂ | F494471 | Magnesium hydroxide Mg(OH)2 | 1309-42-8 |
| MAH-EP | F6180 | EXXELOR ™ VA1803-Exxelor 1803; Maleic | 108-31-6, 31069-12-2 |
| | | anhydride grafted EP (Ethylene-Propylene) | |
| | | copolymer | |
| PETS | F538 | Pentaerythritol tetrastearate (PETS) | 115-83-3 |
| AOX1 | F542 | Tris(2,4-di-tert-butylphenyl) phosphite; | 31570-04-4 |
| | | antioxidant | |
| AOX2 | 25808 | Irganox ® 1098 | 23128-74-7 |
| | | (Benzenepropanamide, N,N′-1,6- | |
| | | hexanediylbis[3,5-bis(1,1-dimethylethyl)-4- | |
| | | hydroxy]) Phenolic prim antioxidant for | |
| | | polyamide | |
| HALS | F5380 | Tinuvin ® 770 | 52829-07-9 |
| | | (bis(2,2,6,6-tetramethyl-4-piperidyl)sebacate) | |
| | | Hindered amine light stabilizer | |
| H₃PO₃ | F4520 | Phosphorous acid (H₃PO₄) 45% | 7664-38-2 |
| OP1 | R513 | TINOPAL ® OB, fluorescent whitening agent | 7128-64-5 |
| | | (optical brightening agent)(2,5- | |
| | | thiophenediylbis(5-tert-butyl-1,3-benzoxazole)) | |
| OP2 | R112632 | Eastman Eastobrite ™ OB-1 (Pulverized) | 1533-45-5 |
| | | (optical brightening agent)(2,5-bis(5-tert-butyl-2- | |
| | | bexozazolyl)thiophene) | |

The compositions as set forth in the Examples below were prepared from the components presented in Table 1.

Formulations were prepared by extruding the pre-blended components using a twin extruder. The polymer base resin, thermally conductive fillers, white pigment, optical brightening agents and any additional additives were first dry blended together, then fed into a The extrudate was cooled using a water bath prior to pelletizing. Components were compounded using a L/D at 40.5 Toshiba® TEM-37BS Twin Screw Extruder co-rotating twin screw extruder at between 250° C. and 300° C.

Molded samples were tested in accordance with the standards presented below.

Thermal conductivity was determined in accordance with ASTM E-1461. Through plane Thermal conductivity (TC) was measured for extruded pellets injection molded into 80 mm by 10 millimeter (mm) by 3 mm bar cut into 10 mm by 10 mm by 3 mm square samples. In plane thermal conductivity was measured on 100 mm by 0.4 mm sheet cut into 25 by 0.4 mm round samples. Thermal diffusivity (α, square centimeters per second ((cm²/s)), specific heat (Cp, Joules per gram degree Kelvin (J/g-K)), and density (ρ, grams per cubic centimeter (g/cm³), according to ASTM D792 using a water immersion method) are also observed. The product of the three values provide the through plane and in plane direction thermal conductivity according to the equation κ=α(T) Cp(T) p(T). Each component was measured three times for accuracy.

Optical properties, such as color and reflectivity, were measured on a ColorEye® 7000A with D65 illumination in a 10° observer in reflection mode. Assessments were made according to the International Commission on Illumination (CIE) providing values for colorimetric coordinates L*, a*, b*. The coordinates correspond to different color attributes: a* represents redness and green; b*, yellow and blue; and L*, whiteness. Values of L* range between 0 and 100. Lower L* values correspond to darkness of a material while values of L* greater than 70 correspond to materials appearing white to the naked eye.

The notched Izod impact (“NII”) test was carried out in accordance with ASTM D256 on 63.5 mm×12.7 mm×3.2 mm molded samples (bars) at 25° C. Data units are J/m.

The unnotched Izod impact (“UNII”) test was performed in accordance with ASTM D4812 on 63.5 mm×12.7 mm×3.2 mm molded samples (bars) at 25° C. Data units are J/m.

Tensile properties were measured with a Tensile Type 1 bar in accordance with ASTM D638 using sample bars prepared in accordance with a (bars having the following dimensions 57 mm×13 mm×3.18 mm×166 mm). Tensile strength for either at break or at yield was reported in units of MPa.

The melt volume rate (MVR) was determined according to ASTM 1238 at 6.7 kilogram (kg) at 285° C. for 6 minutes and 18 minutes (more abusive conditions).

Heat deflection temperature was determined per ASTM D790 with flatwise specimen orientation with a 3.18 mm thick specimen (127 mm×12.7 mm) at 1.82 megapascals (MPa). Data are provided below in units of ° C.

Comparative samples were prepared to assess the performance of formulations including titanium dioxide in a polyamide base resin matrix using boron nitride and magnesium hydroxide as the thermally conductive filler. Table 2 presents the thermally conductive formulations at differing loadings of titanium dioxide.

TABLE 2
Mechanical properties and thermal conductivity of compositions
with varying titanium dioxide

| | Unit | CS1 | CS2 | CS3 | CS4 |
|---|---|---|---|---|---|
| Item Description | | | | | |
| TiO2 | % | | 1 | 4.5 | 5 |
| PA1 | % | 34.24 | 33.1 | 34.24 | 33.1 |
| Mg(OH)2 | % | 55 | 55 | 55 | 55 |
| BN | % | 10 | 10 | 10 | 10 |
| H₃PO₃ | % | 0.01 | 0.15 | 0.01 | 0.15 |
| AOX2 | % | 0.2 | 0.2 | 0.2 | 0.2 |
| PETS | % | 0.2 | 0.2 | 0.2 | 0.2 |
| HALS | % | 0.2 | 0.2 | 0.2 | 0.2 |
| AOX1 | % | 0.15 | 0.15 | 0.15 | 0.15 |
| Test Description | | | | | |
| MVR-Avg | cm³/ | 6.89 | 18.3 | 9.09 | 17.7 |
| (285° C./6.7 kg/ | 10 min | | | | |
| 360 seconds) | | | | | |
| MVR-Avg | cm³/ | 12.5 | 25.9 | 17.4 | 26.5 |
| (285° C./6.7 kg/ | 10 min | | | | |
| 1080 seconds) | | | | | |
| % Ash | % | 48.3 | 46.29 | 46.91 | 43.62 |
| Density-Avg | — | 1.692 | 1.693 | 1.735 | 1.745 |
| Notched Izod Impact | J/m | 23.5 | 22.2 | 22.4 | 22.1 |
| Strength-Avg | | | | | |
| Unnotched Izod | J/m | 228 | 140 | 191 | 152 |
| Impact Strength-Avg | | | | | |
| Deflection temp-Avg | ° C. | 177 | 166 | 174 | 173 |
| Modulus of | MPa | 12278 | 12179 | 12657 | 12856 |
| Elasticity-Avg | | | | | |
| Stress at Break-Avg | MPa | 74.3 | 69.9 | 76.4 | 68.7 |
| Elongation at Break- | % | 0.81 | 0.71 | 0.85 | 0.63 |
| Avg | | | | | |
| L*-Avg | — | 95.6 | 96.5 | 97 | 97.6 |
| a*-Avg | — | −0.1 | −0.4 | −0.6 | −0.6 |
| b*-Avg | — | 2.9 | 3.3 | 3.3 | 2.6 |
| Reflectivity | % | 89.51 | 91.63 | 92.646 | 94.1 |
| Through plane TC | W/m * K | 1.52 | 1.57 | 1.50 | 1.57 |
| In plane TC | W/m * K | 2.93 | 2.56 | 2.95 | 2.64 |

As shown, values for reflectivity increased with the addition of titanium dioxide. As the amount of titanium dioxide was increased, the values for reflectivity further increased.

The effect of the introduction of an optical brightening agent was also observed. Table 3 presents the thermally conductive formulations at varying amounts of titanium dioxide as well as an optical brightening agent.

TABLE 3A
Mechanical and optical properties and thermal conductivity
of compositions with varying titanium
dioxide and a fluorescent optical brightening agent

| | Unit | CS1 | S5 | CS2 | S6 |
|---|---|---|---|---|---|
| Item Description | | | | | |
| TiO₂ | % | | | 1 | 1 |
| OP1 | % | | 0.1 | | 0.055 |
| PA1 | % | 34.24 | 34.24 | 33.1 | 34.24 |
| Mg(OH)2 | % | 55 | 55 | 55 | 55 |
| BN | % | 10 | 10 | 10 | 10 |
| H₃PO₃ | % | 0.01 | 0.01 | 0.15 | 0.01 |
| AOX2 | % | 0.2 | 0.2 | 0.2 | 0.2 |
| PETS | % | 0.2 | 0.2 | 0.2 | 0.2 |
| HALS | % | 0.2 | 0.2 | 0.2 | 0.2 |
| AOX1 | % | 0.15 | 0.15 | 0.15 | 0.15 |
| Test Description | | | | | |
| MVR-Avg | cm³/10 | 6.89 | 11 | 18.3 | 14 |
| 285° C./6.7 kg/ | min | | | | |
| 360 s | | | | | |
| MVR-Avg | cm³/10 | 12.5 | 21.9 | 25.9 | 24 |
| 285° C./6.7 kg/ | min | | | | |
| 1080 s | | | | | |
| % Ash | % | 48.3 | 48.03 | 46.29 | 41.11 |
| Density-Avg | — | 1.692 | 1.698 | 1.693 | 1.710 |
| Notched Izod | J/m | 23.5 | 22.5 | 22.2 | 22.5 |
| Impact | | | | | |
| Strength-Avg | | | | | |
| Unnotched Impact | J/m | 228 | 212 | 140 | 134 |
| Strength-Std | | | | | |
| Deflection temp- | ° C. | 177 | 177 | 166 | 180 |
| Avg | | | | | |
| Modulus of | MPa | 12278 | 13009 | 12179 | 12904 |
| Elasticity-Avg | | | | | |
| Stress at Break- | MPa | 74.3 | 78.5 | 69.9 | 78.4 |
| Avg | | | | | |
| Elongation at | % | 0.81 | 0.77 | 0.71 | 0.84 |
| Break-Avg | | | | | |
| L-Avg | — | 95.6 | 96.8 | 96.5 | 97.3 |
| a-Avg | — | −0.1 | −0.7 | −0.4 | −1.8 |
| b-Avg | — | 2.9 | −1 | 3.3 | 1.4 |
| RI | % | 89.51 | 92.2 | 91.63 | 93.016 |
| Through plane TC | W/m * | 1.52 | 1.49 | 1.57 | 1.78 |
| | K | | | | |
| In plane TC | W/m * | 2.93 | 2.95 | 2.56 | 2.94 |
| | K | | | | |

TABLE 3B
Mechanical and optical properties and thermal conductivity of compositions
with varying titanium dioxide and a fluorescent optical brightening agent

| Item Description | Unit | CS3 | S7 | S8 | CS4 | S9 |
|---|---|---|---|---|---|---|
| TiO₂ | % | 4.5 | 4.5 | 4.5 | 5 | 5 |
| OP1 | % | | 0.055 | 0.1 | | 0.1 |
| PA1 | % | 34.24 | 34.24 | 34.24 | 33.1 | 34.24 |
| Mg(OH)2 | % | 55 | 55 | 55 | 55 | 55 |
| BN | % | 10 | 10 | 10 | 10 | 10 |
| H₃PO₃ | % | 0.01 | 0.01 | 0.01 | 0.15 | 0.01 |
| AOX2 | % | 0.2 | 0.2 | 0.2 | 0.2 | 0.2 |
| PETS | % | 0.2 | 0.2 | 0.2 | 0.2 | 0.2 |
| HALS | % | 0.2 | 0.2 | 0.2 | 0.2 | 0.2 |
| AOX1 | % | 0.15 | 0.15 | 0.15 | 0.15 | 0.15 |
| Test Description | Unit | CS3 | S7 | S8 | CS4 | S9 |
| MVR-Avg | cm³/10 | 9.09 | 10.2 | 12.6 | 17.7 | 5.79 |
| 285° C./6.7 kg/360 s | min | | | | | |
| MVR-Avg | cm³/10 | 17.4 | 19.4 | 24 | 26.5 | 13.8 |
| 285° C./6.7 kg/1800 s | min | | | | | |
| % Ash | % | 46.91 | 44.14 | 43.72 | 43.62 | 52.9 |
| Density-Avg | — | 1.735 | 1.739 | 1.737 | 1.745 | 1.786 |
| Notched Izod Impact | J/m | 22.4 | 23.2 | 23.2 | 22.1 | 22.7 |
| Strength-Avg | | | | | | |
| Unnotched Izod | J/m | 191 | 131 | 206 | 152 | 192 |
| Impact Strength-Avg | | | | | | |
| Deflection temp-Avg | ° C. | 174 | 177 | 176 | 173 | 180 |
| Modulus of Elasticity- | MPa | 12657 | 12982 | 12695 | 12856 | 14427 |
| Avg | | | | | | |
| Stress at Break-Avg | MPa | 76.4 | 76.8 | 76.7 | 68.7 | 70.3 |
| Elongation at Break- | % | 0.85 | 0.81 | 0.85 | 0.63 | 0.56 |
| Avg | | | | | | |
| L-Avg | — | 97 | 97.8 | 97.8 | 97.6 | 97.8 |
| a-Avg | — | −0.6 | −0.7 | −1.5 | −0.6 | −0.9 |
| b-Avg | — | 3.3 | 1.2 | 1.9 | 2.6 | 1.1 |
| RI | % | 92.646 | 94.434 | 94.286 | 94.1 | 94.53 |
| Through plane TC | W/m*K | 1.5 | 1.77 | 1.60 | 1.57 | 1.48 |
| In plane TC | W/m*K | 2.75 | 3.25 | 3.12 | 2.64 | 2.77 |

As shown in Tables 3A and 3B, the addition of the fluorescent whitening agent OP1 further improved reflectivity when compared to samples including only titanium dioxide white pigment and the thermally conductive filler. See samples CS1-CS4 compared to S5-S9. There is thus a synergistic effect among the white pigment, thermally conductive filler, and the optical brightening agent as evidenced by samples S6 to S9 combining all three components. It was also observed that maintaining titanium dioxide at a certain content maintained the enhanced reflectivity.

The effect of another optical brightening agent was also observed. Table 4 presents formulations including thermally conductive filler, white pigment, and Eastman Eastobrite™ fluorescent optical brightening agent.

TABLE 4
Mechanical and optical properties and thermal conductivity of compositions
with varying titanium dioxide and a fluorescent optical brightening agent

| Item | | | | | | | | | |
|---|---|---|---|---|---|---|---|---|---|
| Description | Unit | CS1 | S10 | CS2 | S11 | S12 | S13 | CS4 | S14 |
| TiO₂ | % | | | 1 | 1 | 4.5 | 4.5 | 5 | 5 |
| OP₂ | % | | 0.1 | | 0.055 | 0.055 | 0.1 | | 0.1 |
| PA1 | % | 34.24 | 34.24 | 33.1 | 34.24 | 34.24 | 34.24 | 33.1 | 34.24 |
| Mg(OH)2 | % | 55 | 55 | 55 | 55 | 55 | 55 | 55 | 55 |
| BN | % | 10 | 10 | 10 | 10 | 10 | 10 | 10 | 10 |
| H₃PO₃ | % | 0.01 | 0.01 | 0.15 | 0.01 | 0.01 | 0.01 | 0.15 | 0.01 |
| AOX2 | % | 0.2 | 0.2 | 0.2 | 0.2 | 0.2 | 0.2 | 0.2 | 0.2 |
| PETS | % | 0.2 | 0.2 | 0.2 | 0.2 | 0.2 | 0.2 | 0.2 | 0.2 |
| HALS | % | 0.2 | 0.2 | 0.2 | 0.2 | 0.2 | 0.2 | 0.2 | 0.2 |
| AOX1 | % | 0.15 | 0.15 | 0.15 | 0.15 | 0.15 | 0.15 | 0.15 | 0.15 |
| Test | | | | | | | | | |
| Description | Unit | CS1 | S10 | CS2 | S11 | S12 | S13 | CS4 | S14 |
| MVR-Avg | cm³/10 | 6.89 | 14.1 | 18.3 | 18.1 | 12.3 | 16.2 | 17.7 | 6.63 |
| (285° C./ | min | | | | | | | | |
| 6.7 kg/360 s) | | | | | | | | | |
| MVR-Avg | cm³/10 | 12.5 | 26 | 25.9 | 30.5 | 17.9 | 26.3 | 26.5 | 10.3 |
| (285° C./ | min | | | | | | | | |
| 6.7 kg/1080 s) | | | | | | | | | |
| % Ash | % | 48.3 | 48 | 46.29 | 41.1 | 44.68 | 41.82 | 43.62 | 53.56 |
| Density-Avg | — | 1.692 | 1.693 | 1.6930 | 1.709 | 1.736 | 1.737 | 1.745 | 1.796 |
| Notched Izod | J/m | 23.5 | 27.1 | 22.2 | 22.2 | 22.5 | 22.8 | 22.1 | 22.9 |
| Impact | | | | | | | | | |
| Strength-Avg | | | | | | | | | |
| Unnotched Izod | — | 228 | 242 | 140 | 213 | 151 | 200 | 152 | 199 |
| Impact | | | | | | | | | |
| Strength-Avg | | | | | | | | | |
| Deflection | ° C. | 177 | 179 | 166 | 178 | 177 | 177 | 173 | 180 |
| temp-Avg | | | | | | | | | |
| Modulus of | MPa | 12278 | 12845 | 12179 | 12986 | 12958 | 13122 | 12856 | 15127 |
| Elasticity-Avg | | | | | | | | | |
| Stress at Break- | MPa | 74.3 | 78.5 | 69.9 | 79.4 | 76.4 | 79.4 | 68.7 | 76.7 |
| Avg | | | | | | | | | |
| Elongation at | % | 0.81 | 0.78 | 0.71 | 0.87 | 0.82 | 0.86 | 0.63 | 0.59 |
| Break-Avg | | | | | | | | | |
| L-Avg | — | 95.6 | 98.2 | 96.5 | 97.9 | 97.9 | 98.4 | 97.6 | 98.6 |
| a-Avg | — | −0.1 | −11.7 | −0.4 | −7.5 | −5.8 | −7.4 | −0.6 | −7.7 |
| b-Avg | — | 2.9 | 15.7 | 3.3 | 10.6 | 8.2 | 11.6 | 2.6 | 11.3 |
| Reflectivity | % | 89.51 | 91.91 | 91.63 | 92.722 | 93.36 | 94.142 | 94.1 | 94.44 |
| Through plane | W/m*K | 1.52 | 1.36 | 1.57 | 1.34 | 1.33 | 1.25 | 1.57 | 1.53 |
| TC | | | | | | | | | |
| In plane TC | W/m*K | 2.93 | 2.44 | 2.56 | 2.59 | 2.45 | 2.43 | 2.64 | 2.82 |

Similar results were observed for the Eastman Eastobrite™ (OP2) formulations samples S11, S12, S13, and S14. The combined effect of the white pigment, optical brightening agent and thermally conductive filler exhibited comparable reflectivity and maintained mechanical properties. Improved reflectivity was observed for samples with higher amounts of the titanium dioxide, even in the presence of the optical brightening agent OP2.

Formulations containing only magnesium hydroxide as a thermally conductive filler were also observed for mechanical and optical properties. Table 5 presents the formulations.

TABLE 5
Mechanical and optical properties and thermal conductivity
of compositions with varying titanium dioxide,
an optical brightening agent and a thermally conductive filler

| | Unit | CS5 | S15 | S16 | S17 |
|---|---|---|---|---|---|
| Item Description | | | | | |
| TiO₂ | % | | 15 | | 15 |
| OP1 | % | | | 0.1 | 0.1 |
| PA2 | % | 44.235 | 44.235 | 44.235 | 44.235 |
| Mg(OH)₂ | % | 55 | 55 | 55 | 55 |
| H₃PO₃ | % | 0.015 | 0.015 | 0.015 | 0.015 |
| AOX2 | % | 0.2 | 0.2 | 0.2 | 0.2 |
| PETS | % | 0.2 | 0.2 | 0.2 | 0.2 |
| HALS | % | 0.2 | 0.2 | 0.2 | 0.2 |
| AOX1 | % | 0.15 | 0.15 | 0.15 | 0.15 |
| Test Description | | | | | |
| MVR-Avg | cm³/10 | 49.3 | 15.6 | 45.4 | 22.1 |
| (285° C./6.7 | min | | | | |
| kg/360 s) | | | | | |
| MVR-Avg | cm³/10 | 80.9 | 30 | 73.8 | 34.3 |
| (285° C./6.7 kg/ | min | | | | |
| 1080 s) | | | | | |
| % Ash | % | 37.69 | 52.54 | 37.64 | 51.84 |
| Density-Avg | — | 1.554 | 1.833 | 1.556 | 1.822 |
| Notched Izod | J/m | 35.3 | 39.4 | 34.2 | 38 |
| Impact | | | | | |
| Strength-Avg | | | | | |
| Unnotched Izod | — | 366 | 290 | 397 | 303 |
| Impact | | | | | |
| Strength-Avg | | | | | |
| Deflection temp | ° C. | 127 | 151 | 123 | 146 |
| Modulus of | MPa | 7209 | 11190 | 7335 | 11015 |
| Elasticity-Avg | | | | | |
| Stress at Break- | MPa | 76.1 | 69.8 | 73.6 | 77 |
| Avg | | | | | |
| Elongation at | % | 1.53 | 0.73 | 1.34 | 0.88 |
| Break-Avg | | | | | |
| L-Avg | — | 81.3 | 97.7 | 86.2 | 98.1 |
| a-Avg | — | −2.1 | −0.5 | −3 | −0.7 |
| b-Avg | — | 11.6 | 2.2 | 4.8 | 1.6 |
| Reflectivity | % | 59.28% | 94.48% | 67.99% | 95.17% |
| Through plane | W/m * | 1.11 | 1.06 | 1.04 | 1.13 |
| TC | K | | | | |
| In plane TC | W/m * | 1.83 | 1.77 | 1.77 | 1.77 |
| | K | | | | |

A significantly lower reflectivity was observed for comparative sample CS5 having only the magnesium hydroxide thermally conductive filler and having neither the white pigment or the optical brightening agent (59.28% reflectivity). Sample S16 showed a moderate increase in reflectivity to 68% for a formulation having the optical brightening agent and thermally conductive filler, but without the white pigment titanium dioxide. Here, however, mechanical properties of MVR and impact strength were maintained. Finally, sample S17 combining the magnesium hydroxide, optical brightening agent, and white pigment exhibited the highest values for reflectivity. Values for impact strength, the color coordinates, and modulus were improved while values for the flow rate decreased.

The patentable scope of the disclosure is defined by the claims, and can include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A polymer composition comprising:
from about 20 wt. % to about 80 wt. % of a polymer base resin;
from about 1 wt. % to about 70 wt. % of a thermally conductive filler;
from about 0.1 wt. % to about 50 wt. % of a white pigment; and
from about 0.001 wt. % to about 10 wt. % of an optical brightening agent,
wherein the polymer composition exhibits a through plane thermal conductivity of at least about 0.3 W/mK and a reflectivity of at least about 80%, and
wherein the combined weight percent value of all components does not exceed about 100 wt. %, and all weight percent values are based on the total weight of the polymer composition.

2. A polymer composition comprising:
from about 20 wt. % to about 60 wt. % of a polymer base resin;
from about 1 wt. % to about 70 wt. % of a thermally conductive filler;
from about 0.1 wt. % to about 25 wt. % of at least one white pigment; and
from about 0.001 wt. % to about 10 wt. % of an optical brightening agent
wherein the polymer composition exhibits a through plane thermal conductivity of at least about 0.3 W/mK and a reflectivity of at least about 90%, and
wherein the combined weight percent value of all components does not exceed about 100 wt. %, and all weight percent values are based on the total weight of the polymer composition.

3. The polymer composition of claim 1, wherein the polymer base resin comprises a polyamide polymer or a combination of polyamide polymers.

4. The polymer composition of claim 1, wherein the thermally conductive filler comprises zinc sulfide, calcium oxide, magnesium oxide, zinc oxide, titanium dioxide, tin dioxide, chromium oxide, calcium carbonate, mica, barium oxide, barium sulfate, calcium sulfate, wollastonite, zirconium oxide, silicon oxide, glass beads, glass fiber, magnesium aluminate, dolomite, coated graphite, magnesium hydroxide, talc, boehmite, diaspore, gibbsite, clay; aluminum nitride, aluminum carbide, aluminum oxide, boron nitride, aluminum oxynitride, magnesium silicon nitride, silicon carbide, silicon nitride, tungsten oxide, aluminum phosphide, beryllium oxide, boron phosphide, cadmium sulfide, gallium nitride, zinc silicate, tungsten oxide or a combination thereof.

5. The polymer composition of claim 1, wherein the thermally conductive filler comprises one or more of magnesium hydroxide and boron nitride or a combination thereof.

6. The polymer composition of claim 1, wherein the thermally conductive filler has a thermal conductivity of at least about 5 W/m*K.

7. The polymer composition of claim 1, wherein the white pigment comprises titanium dioxide, zinc sulfate, antimony oxide, zinc oxide, a lead carbonate, lithopone, or a combination thereof.

8. The polymer composition of claim 1, wherein the white pigment comprises titanium dioxide.

9. The polymer composition of claim 1, wherein the polymer composition comprises white pigment in an amount between 1 wt. % and 10 wt. %.

10. The polymer composition of claim 1, wherein the optical brightening agent comprises a fluorescent optical brightening agent.

11. The polymer composition of claim 1, wherein the optical brightening agent comprises 4,4′-bis(2-benzoxazolyl) stilbene.

12. The polymer composition of claim 1, wherein the optical brightening agent comprises 2,5-bis(5-tert-butyl-2-benzoxazolyl)thiophene.

13. The polymer composition of claim 1, wherein the polymer composition further comprises an additive.

14. The polymer composition of claim 13, wherein the additive comprises a pigment, a dye, a filler, a plasticizer, a fiber, a flame retardant, an antioxidant, a lubricant, wood, glass, metal, an ultraviolet agent, an anti-static agent, an anti-microbial agent, or combinations thereof.

15. The polymer composition of claim 1, further comprising talc.

16. An article comprising the polymer composition of claim 1.

17. The article of claim 16, wherein the article is an LED heat sink or an electronics housing.
